(19) United States
(12) Patent Application Publication
(10) Pub. No.: US 2003/0044517 A1
(43) Pub. Date: Mar. 6, 2003

(54) Method for manufacturing electroluminescence element and evaporation mask

(76) Inventors: Ryuji Nishikawa, Gifu-shi (JP); Tsutomu Yamada, Motosu-gun (JP)

Correspondence Address: CANTOR COLBURN, LLP, 55 GRIFFIN ROAD SOUTH, BLOOMFIELD, CT, 06002

(21) Appl. No.: 10/232,625

(22) Filed: Aug. 30, 2002

(30) Foreign Application Priority Data
Aug. 31, 2001 (JP) 2001-264707

(51) Int. Cl. B05D 5/12; C23C 16/00; B05D 1/32

(52) U.S. Cl. 427/66; 427/248.1; 427/68; 427/282

(57) ABSTRACT

An evaporation mask is placed between an evaporation source and a plastic substrate. An evaporation substance from the evaporation source is allowed to selectively pass through one or more openings formed on the evaporation mask corresponding to the pattern of an evaporation layer of an EL element, to form the evaporation layer on the plastic substrate. As the material for the evaporation mask, a material whose thermal expansion coefficient is similar to (for example, within a range of ±30% of) the thermal expansion coefficient of the plastic substrate, for example, a plastic material such as a polyimide, is employed. It is preferable to employ a material having a thermal endurance which is, for example, at least approximately 50° C. higher than the thermal endurance of the plastic substrate. By employing such a material for the evaporation mask, it is possible to ensure that the plastic substrate and the evaporation mask will exhibit the same degree of thermal deformation during evaporation, thereby enabling improvement in the precision of evaporation patterning.

### BACKGROUND OF THE INVENTION

1. Field of the Invention

The present invention relates to a method for manufacturing an EL element formed on a plastic substrate.

2. Description of the Related Art

A type of EL display panel is known in which an organic EL element or the like is employed as an emissive element in each pixel. Expanding use of such an EL display panel as a self-illuminating flat panel is widely expected.

As an organic EL element, a structure is known, for example, in which an anode made of a transparent electrode such as ITO (Indium Tin Oxide) and a cathode made of a metal electrode such as Al or a magnesium alloy are layered on a glass substrate, with an organic layer including an emissive layer provided between the anode and cathode.

For manufacturing such an organic EL element, an evaporation method is employed for forming the organic layer and the metal electrode. During the evaporation, an evaporation mask is used onto which openings are formed corresponding to a predetermined pattern desired for each layer. For example, because a material for an organic layer used in an organic EL element is vulnerable to moisture, it is not possible to employ a method, for example, in which an organic layer is first formed on the entire surface of the substrate and then the organic layer is etched and patterned into a predetermined shape. Therefore, a method is employed in which the region for evaporation is limited or defined in advance using an evaporation mask so that the organic layer is patterned at the same time as the evaporation.

In such a method, evaporation is performed by setting an element substrate, which is the processing target, within a vacuum chamber with the surface for evaporation facing downwards, placing an evaporation mask between the surface for evaporation of the substrate and an evaporation source, heating the evaporation source to vaporize the material to be evaporated, and adhering the evaporation material onto the substrate surface through the openings on the mask. During evaporation, although the ambient temperature is set at room temperature, because the evaporation source is heated for vaporizing the evaporation material, a higher than normal temperature is observed in the region around the evaporation source, on the mask which blocks the high-temperature, incoming evaporation substance, and on the element substrate to which the evaporation substance is to be deposited.

Typically, a nickel mask is used as the mask because methods for precisely and stably manufacturing nickel masks are well established. More specifically, a method is well established in which a resist of a predetermined pattern is formed on a stainless base material or the like and a nickel mask is formed through electrodeposition, and, thus, stable production of high precision masks is possible.

In organic EL display panels currently being developed for mass production, a glass substrate having a high thermal durability is used. However, employment of a plastic substrate is being tested instead of a glass substrate for further increasing the size and further decreasing the thickness of the display panel. In an organic EL element, because light is emitted from the region within the organic layer between the anode and cathode, when the formation position of the organic layer and the formation position of the electrode do not match, variations in light emission area and in light emission intensity are created among the pixels. Therefore, for manufacturing an EL display panel, there is a need for precisely pattern each of the layers to be layered. However, there had been a problem in that sufficient patterning precision cannot be achieved in the evaporation layer evaporated using the nickel mask.

After extensive experiment and study, the present inventors have found that the reduction in the patterning precision is caused by the fact that the thermal expansion coefficient of the conventional nickel mask (130×10⁻⁷/K) significantly differs from that of the plastic substrate.

### SUMMARY OF THE INVENTION

Accordingly, an object of the present invention is to provide a method for manufacturing an EL display panel in which a precise patterning can be achieved during evaporation.

In order to achieve at least the object mentioned above, the present invention has the following characteristics.

According to one aspect of the present invention, there is provided a method for manufacturing a plurality of electroluminescence elements on a plastic substrate, wherein an evaporation mask made of a material having a thermal expansion coefficient falling within a range of ±30% of the thermal expansion coefficient of the plastic substrate is used when a material to be evaporated as an element is vaporized at an evaporation source and is evaporated onto a plastic substrate to form an evaporation layer of an electroluminescence element, the evaporation mask is placed between the evaporation source and the plastic substrate, and the evaporation layer is patterned simultaneously with the evaporation of the material to be evaporated as an element.

According to another aspect of the present invention, there is provided an evaporation mask onto which one or more openings are formed for allowing selective passage of an evaporation substance from an evaporation source onto a plastic substrate to form an evaporation layer of an electroluminescence element in a predetermined pattern, the evaporation mask placed between the evaporation source and the plastic substrate when the evaporation layer is formed on the plastic substrate, wherein the evaporation mask is made of a material having a thermal expansion coefficient falling within a range of ±30% of the thermal expansion coefficient of the plastic substrate.

According to yet another aspect of the present invention, the material for the evaporation mask has a thermal endurance which is at least approximately 50° C. higher than the thermal endurance of the plastic substrate.

As described, by using, as the material for the evaporation mask, a material whose thermal expansion coefficient is similar to that of the plastic used as the material for the plastic substrate of the element, it is possible to create a situation wherein the thermal deformation of the evaporation mask is similar to the thermal deformation of the plastic substrate when heated by the evaporation source. Therefore, the thermal deformation of the evaporation mask can be substantially cancelled and an evaporation layer can be precisely patterned on the plastic substrate.

According to another aspect of the present invention, there is provided a method for manufacturing a plurality of electroluminescence elements on a plastic substrate, wherein when a material to be evaporated as an element is vaporized at an evaporation source and is evaporated onto a plastic substrate to form an evaporation layer of an electroluminescence element, an evaporation mask is placed between the evaporation source and the plastic substrate using a mask supporting mechanism in which a material having a thermal expansion coefficient within a range of ±30% of the thermal expansion coefficient of the plastic substrate is used at least for a mask holding section, and the evaporation layer is patterned simultaneously with the evaporation of the material to be evaporated as an element.

According to another aspect of the present invention, it is preferable that in the method for manufacturing, each of the materials for the evaporation mask and for the mask holding section has a thermal endurance which is at least approximately 50° C. higher than the thermal endurance of the plastic substrate. By using a material having a thermal endurance which is at least 50° C. higher than the thermal endurance of the plastic substrate, it is possible to achieve sufficient durability for the evaporation mask and the mask holding section which are placed closer to the evaporation source than the plastic substrate.

According to another aspect of the present invention, there is provided a method for manufacturing a plurality of electroluminescence elements on a plastic substrate, wherein an evaporation mask made of a material having a thermal expansion coefficient within a range of ±30% of the thermal expansion coefficient of a plastic substrate is used when a material to be evaporated as an element is vaporized at an evaporation source and is evaporated onto the plastic substrate to form an evaporation layer of an electroluminescence element, and the evaporation mask is placed between the evaporation source and the plastic substrate using a mask supporting mechanism in which a material having a thermal expansion coefficient within a range of ±30% of the thermal expansion coefficient of the plastic substrate is used at least for a mask holding section, and the evaporation layer is patterned simultaneously with the evaporation of the material to be evaporated as an element.

In this manner, by using a material, for the mask holding section, having a thermal expansion coefficient similar to the plastic substrate, that is, a thermal expansion coefficient similar also to the evaporation mask, it is possible to inhibit the thermal stress between the holding section and the evaporation mask even when the temperature of the holding section is increased during evaporation, and to prevent application of excessive stress to the evaporation mask.

### BRIEF DESCRIPTION OF THE DRAWINGS

FIG. 1 is a diagram for explaining the evaporation process according to a preferred embodiment of the present invention.

FIG. 2 is a planer diagram showing an example of a planer structure of an evaporation mask according to a preferred embodiment of the present invention.

FIG. 3 is a diagram showing a partial cross sectional structure of a pixel in an organic EL display panel manufactured through a method according to a preferred embodiment of the present invention.

### DESCRIPTION OF PREFERRED EMBODIMENT

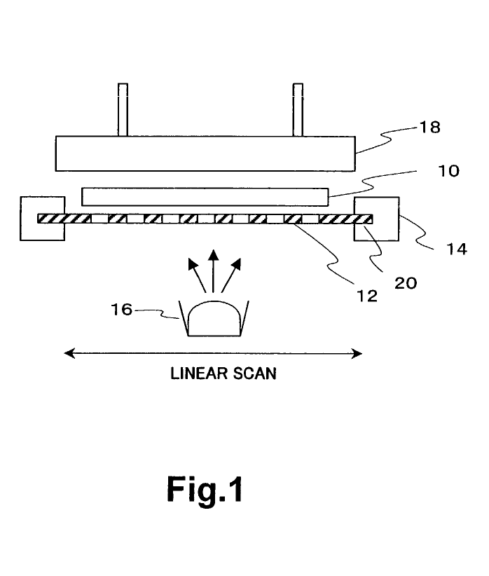

A preferred embodiment of the present invention will now be described referring to the drawings. FIG. 1 is a diagram for explaining an example method for manufacturing according to a preferred embodiment.

An evaporation mask 12 is placed below a plastic substrate 10 for forming a portion of an EL panel, the evaporation mask 12 having an overall size greater than that of the plastic substrate 10. Although in FIG. 1, the plastic substrate 10 and the evaporation mask 12 are shown separated from each other, in practice the plastic substrate 10 and the evaporation mask 12 are in contact with each other over almost their entire surface. The ends of the mask 12 are supported by a supporting mechanism 14.

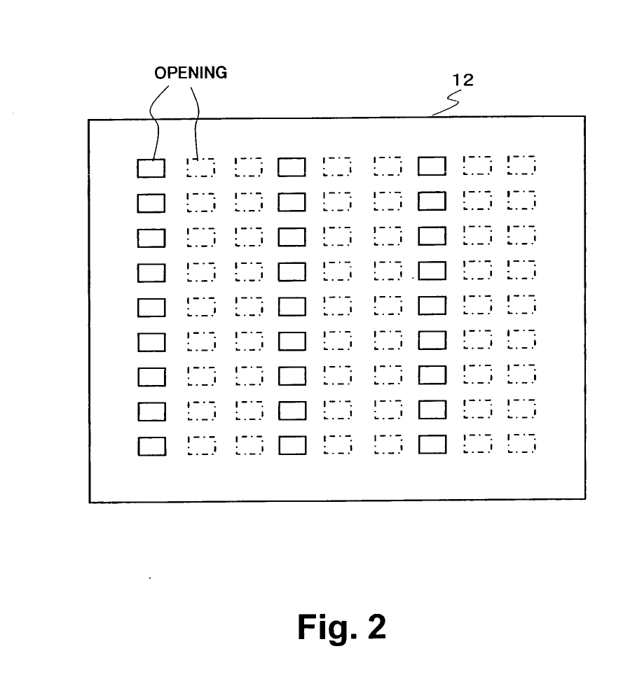

Below the evaporation mask 12, an evaporation source 16 is placed for heating an evaporation material to a temperature of, for example, approximately 300° C. In this example, the evaporation source 16 is moveable in the right and left direction of the page and into and out of the page. By moving the evaporation source 16, evaporation substance can be evaporated onto the entire surface of the plastic substrate 10 through the openings on the mask 12. On the surface of the evaporation mask 12, openings are provided that correspond to the pattern of the evaporation layer to be formed (organic layer of the organic EL element or the like). For example, in the evaporation mask 12 used for forming an organic emissive layer independently for each pixel, openings are formed in a pattern as shown in FIG. 2.

FIG. 2 shows an example planer structure of the evaporation mask 12 which is an example mask for forming an organic layer such as the emissive layer of the organic EL element. The structure of the organic EL element will be described below. The openings in the mask 12 are formed only at the positions corresponding to the light emitting regions of the same color among the light emitting regions of R, G, and B organic EL elements which are placed in a matrix form on a plastic substrate. The mask 12 can be used for forming organic EL elements using different organic emissive materials for R, G, and B. When an organic layer or an emissive layer of one color is formed, the mask 12 is placed below the plastic substrate 10 as shown in FIG. 1 and evaporation isperformed. Then, the evaporation material in the evaporation source 16 is changed, and the evaporation mask 12 is changed to another evaporation mask for another color, or, alternatively, the same evaporation mask is moved so that the mask openings are at positions shown by a one dotted chain line in FIG. 1 relative to the plastic substrate 10. Then, the organic layers for other colors are sequentially formed through evaporation.

In addition, above the plastic substrate 10, an electrostatic suction mechanism 18 or the like is provided as necessary, so that the evaporation mask 12 can be suctioned in order to prevent flexure of the central portion of the evaporation mask 12 toward the downward direction due to its own weight.

With such a device, a predetermined evaporation material is set in the evaporation source 16, a corresponding mask 12 is set, and the evaporation is performed. In practice, the evaporation material of the evaporation source 16 and the mask 12 are changed and each of the layers forming the EL panel are layered in sequence through evaporation.

In the preferred embodiment, as described above, a plastic substrate 10 is employed as the EL panel substrate and a material having a thermal expansion coefficient within a range of ±30% of the thermal expansion coefficient of the plastic substrate is employed as the material for the evaporation mask 12. A suitable material may be a plastic, for example. Because of this, when the evaporation source 16 is provided to be moveable as in the present embodiment, it is possible to obtain similar degree of thermal deformation for the evaporation mask 12 and for the plastic substrate 10 in a local region, for thermal deformation resulting from an increase in the temperature when the evaporation source moves near the local region.

In addition, because the evaporation mask 12 is placed closer to the high temperature evaporation source 16 than the plastic substrate 10 which is the evaporation target, the temperature of the mask 12 becomes approximately 10° C. to 30° C. higher than the temperature of the plastic substrate 10, although the specific difference in temperature will vary depending on the distance from the evaporation source 16. Therefore, it is preferable that, in consideration of the temperature difference between the mask and the substrate, the thermal endurance of the evaporation mask 12 be 40° C. to 50° C. or more higher than that of the substrate 10. Moreover, in consideration of the temperature difference between the evaporation mask 12 and the plastic substrate 10, it is even more preferable that the material of the mask be selected so that the thermal expansion coefficient of the mask is lower than the thermal expansion coefficient of the plastic substrate by an amount corresponding to the temperature difference.

When a polycarbonate (PC) having a thermal expansion coefficient of approximately 2.7×10⁻⁵/K (kelvin) and a thermal endurance (glass transition temperature) of 150° C., for example, is used as the material for the plastic substrate 10, examples of the plastic material used for the evaporation mask 12 include a polycarbonate which is the same material (including a high thermal endurance polycarbonate having a glass transition temperature of approximately 205° C.), a polyimide (PI) (having a thermal expansion coefficient of 2.0×10⁻⁵/K 2.5×10⁻⁵/K and a glass transition temperature of approximately 275° C.), a polyarylate (PAR) (having a thermal expansion coefficient of 2.0×10⁻⁵/K 2.5×10⁻⁵/K and a glass transition temperature of approximately 215° C.), and a polyethersulphone (PES) (having a thermal expansion coefficient of 2.5×10⁻⁵/K and a glass transition temperature of approximately 215° C.), etc., each of which has a thermal expansion coefficient similar to that of the polycarbonate.

Each of these materials has a thermal endurance (glass transition temperature) of at least approximately 50° C. higher than the thermal endurance of the polycarbonate which is approximately 150° C. Therefore, sufficient durability can be achieved by using the polyimide or the like as the material for the evaporation mask 12, even when the temperature of the evaporation mask 12 becomes higher than that of the plastic substrate 10 as described above.

The material for the evaporation mask is not limited to the plastic materials exemplified above. By using a material having a thermal expansion coefficient similar to that of the plastic substrate 10 (for example, a material whose thermal expansion coefficient is within a range of ±30%, and more preferably, ±26% of the thermal expansion coefficient of the plastic substrate) as the material for the evaporation mask, the thermal expansion of the evaporation mask 12 and the thermal expansion of the plastic substrate 10 can be cancelled out during evaporation, and the influence of the increase in temperature can thereby be eliminated to allow precise patterning.

It is desirable that the mask supporting mechanism (mask frame) 14 be constructed such that, for example, when the supporting mechanism 14 is configured to hold the ends of the evaporation mask 12, at least a mask holding section 20 of the supporting mechanism 14 is made of a material whose thermal expansion coefficient is similar to that of the evaporation mask 12. In other words, it is desirable to use a mask supporting mechanism 14 in which a material such as any of the above-described plastics which can be used for the evaporation mask 12, Al (having a thermal expansion coefficient of 2.4×10⁻⁵/K), and Ni material having a higher thermal expansion coefficient than the conventional Ni mask material (having a thermal expansion coefficient of 3.51×10⁻⁵/K˜1.89×10⁻⁵/K) is used for the mask holding section 20. By using such a material, it is possible to prevent application of excessive stress to the evaporation mask 12 when the temperature of the holding section is increased by, for example, heat conduction. With such a structure, because the evaporation mask 12 and the mask holding section 20 deform similarly, the holding strength tends not be weakened. Also, regardless of the material for the evaporation mask, by using a material having a thermal expansion coefficient within a range of ±30% of the thermal expansion coefficient of the plastic substrate, and more preferably, also having a thermal endurance which is at least approximately 50° C. higher than the thermal endurance of the plastic substrate, at least for the mask holding section 20 of the mask supporting mechanism 14 as described above, it is possible to achieve sufficient mask supporting functionality and durability necessary for the mask supporting mechanism 14 which is placed closer to the evaporation source 16 than the plastic substrate.

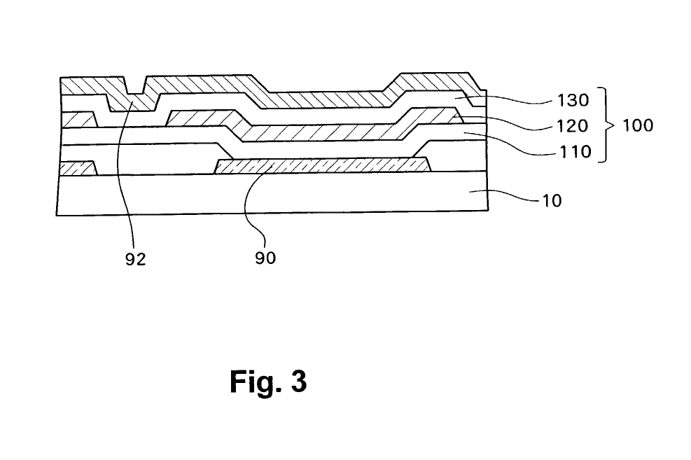

An organic EL element may have a cross sectional structure as shown in FIG. 3, for example. As shown in FIG. 3, a first electrode 90, an organic layer 100, and a second electrode 92 are layered on a plastic substrate 10 in that order. The first electrode 90 is a transparent electrode made of an ITO (Indium Tin Oxide) or the like and functions as the anode. The second electrode 92 is a metal electrode made of, for example, aluminum or an aluminum alloy and functions as the cathode. The organic layer 100 comprises, for example, a hole transport layer 110, an emissive layer 120, and an electron transport layer 130, layered in that order from the first electrode 90. Among these layers forming the organic EL element, the organic layer 100, the second electrode 92, etc. are formed through evaporation. An evaporation mask 12 as described above and onto which openings are formed corresponding to the patterns required for the layer to be evaporated is employed. In an active matrix type organic EL panel in which an organic EL element provided in each pixel is individually controlled by a switching element such as a thin film transistor, a switching element is formed between the first electrode 90 and the plastic substrate 10. In a passive matrix type panel in which the switching elements are not used, the first electrode 90 and the second electrode 92 each of which having a striped shape are formed in directions to intersect each other with the organic layer 100 in between. In such a structure, when it is desired to obtain a full-color display panel by forming organic EL elements on one panel, each EL element showing light emission color of R, G, and B, emissive layers having patterns independent for each color of R, G, and B must be formed, or, alternatively, emissive layers having independent patterns for each pixel must be formed. In particular, when emissive layer or the like is to be formed by evaporation independently for each pixel, a high precision is required because of the very narrow margin in the positional relationship between the layer to be evaporated and the other layers. Because with the present invention a material whose thermal expansion coefficient is similar to that of the plastic substrate 10 is used for the evaporation mask 12, the difference in the amount of deformation between the plastic substrate 10 and the evaporation mask 12 during the evaporation is small, thereby enabling precise patterning.

What is claimed is:

1. A method for manufacturing a plurality of electroluminescence elements on a plastic substrate, wherein
an evaporation mask made of a material having a thermal expansion coefficient within a range of ±30% of the thermal expansion coefficient of a plastic substrate is used when a material to be evaporated as an element is vaporized at an evaporation source and is evaporated onto said plastic substrate to form an evaporation layer of an electroluminescence element; and
said evaporation mask is placed between said evaporation source and said plastic substrate and said evaporation layer is patterned simultaneously with the evaporation of said material to be evaporated as an element.

2. A method for manufacturing according to claim 1, wherein
the material for said evaporation mask has a thermal endurance which is at least approximately 50° C. higher than the thermal endurance of said plastic substrate.

3. A method for manufacturing a plurality of electroluminescence elements on a plastic substrate, wherein
when a material to be evaporated as an element is vaporized at an evaporation source and is evaporated onto a plastic substrate to form an evaporation layer of an electroluminescence element, an evaporation mask is placed between said evaporation source and said plastic substrate using a mask supporting mechanism in which a material having a thermal expansion coefficient within a range of ±30% of the thermal expansion coefficient of said plastic substrate is used at least for a mask holding section, and said evaporation layer is patterned simultaneously with the evaporation of said material to be evaporated as an element.

4. A method for manufacturing according to claim 3, wherein
each of the materials for said evaporation mask and for said mask holding section has a thermal endurance which is at least approximately 50° C. higher than the thermal endurance of said plastic substrate.

5. A method for manufacturing a plurality of electroluminescence elements on a plastic substrate, wherein
an evaporation mask made of a material having a thermal expansion coefficient within a range of ±30% of the thermal expansion coefficient of a plastic substrate is used when a material to be evaporated as an element is vaporized at an evaporation source and is evaporated onto said plastic substrate to form an evaporation layer of an electroluminescence element, and
said evaporation mask is placed between said evaporation source and said plastic substrate using a mask supporting mechanism in which a material having a thermal expansion coefficient within a range of ±30% of the thermal expansion coefficient of said plastic substrate is used at least for a mask holding section, and said evaporation layer is patterned simultaneously with the evaporation of said material to be evaporated as an element.

6. A method for manufacturing according to claim 5, wherein
each of the materials for said evaporation mask and for said mask holding section has a thermal endurance which is at least approximately 50° C. higher than the thermal endurance of said plastic substrate.

7. An evaporation mask onto which one or more openings are formed for allowing selective passage of an evaporation substance from an evaporation source onto a plastic substrate to form an evaporation layer of an electroluminescence element in a predetermined pattern, said evaporation mask placed between said evaporation source and said plastic substrate when said evaporation layer is formed on said plastic substrate, wherein
said evaporation mask is made of a material having a thermal expansion coefficient within a range of ±30% of the thermal expansion coefficient of said plastic substrate.

8. An evaporation mask according to claim 7, wherein
the material for said evaporation mask has a thermal endurance which is at least approximately 50° C. higher than the thermal endurance of said plastic substrate.
